(19) United States
(12) Patent Application Publication
(10) Pub. No.: US 2024/0222085 A1
(43) Pub. Date: Jul. 4, 2024

(54) PLASMA PROCESSING METHOD AND PLASMA PROCESSING APPARATUS INCLUDING APPLYING A VOLTAGE TO A LOWER ELECTRODE IN A SUBSTRATE SUPPORT WITH A GAS SUPPLIED INTO A CHAMBER

(71) Applicant: Tokyo Electron Limited, Tokyo (JP)

(72) Inventors: Koichiro NAKAMURA, Miyagi (JP); Norihisa KIYOFUJI, Hwaseong-si (KR)

(73) Assignee: Tokyo Electron Limited, Tokyo (JP)

(21) Appl. No.: 18/605,902

(22) Filed: Mar. 15, 2024

Related U.S. Application Data
(63) Continuation of application No. PCT/JP2022/044981, filed on Dec. 6, 2022.

(30) Foreign Application Priority Data
Feb. 3, 2022 (JP) 2022-015560

(51) Int. Cl. H01J 37/32

(52) U.S. Cl. CPC H01J 37/32311; H01J 37/32201; H01J 37/3222; H01J 37/32449; H01J 37/32715; H01J 37/32174; H01J 37/32238; H01J 2237/327; H01J 2237/335

(57) ABSTRACT

A plasma processing method is implementable with a plasma processing apparatus. The plasma processing method includes applying a voltage to a lower electrode in a substrate support with a gas being supplied into a chamber in the plasma processing apparatus. The substrate support is located in the chamber. The plasma processing method further includes generating plasma by providing a radio-frequency wave after application of the voltage to the lower electrode is started. In the method, the applying of the voltage and the generating of the plasma are performed without an object on a substrate support surface of the substrate support.

### CROSS-REFERENCE TO RELATED APPLICATIONS

This application is a bypass continuation application of international application No. PCT/JP2022/044981 having an international filing date of Dec. 6, 2022 and designating the United States, the international application being based upon and claiming the benefit of priority from Japanese Patent Application No. 2022-015560, filed on Feb. 3, 2022, the entire contents of each are incorporated herein by reference.

### FIELD

Embodiments of the disclosure relate to a plasma processing method and a plasma processing apparatus.

### BACKGROUND

A plasma processing apparatus is used to process substrates. When substrates are processed using a plasma processing apparatus, the inner wall surfaces of the chamber are contaminated with byproducts. The chamber is thus cleaned. Patent Literature 1 describes a method for cleaning a chamber. This cleaning method uses microwaves to generate plasma in cleaning.

### CITATION LIST

### Patent Literature

Patent Literature 1: Japanese Unexamined Patent Application Publication No. 2021-34515

### SUMMARY

One or more aspects of the disclosure are directed to a technique for reducing the time taken to ignite plasma in plasma processing performed without an object on a substrate support surface of a substrate support and for reducing variations in the time taken to ignite plasma.

A plasma processing method according to one exemplary embodiment is implementable with a plasma processing apparatus. The plasma processing method includes (a) applying a voltage to a lower electrode in a substrate support with a gas being supplied into a chamber in the plasma processing apparatus. The substrate support is located in the chamber. The plasma processing method further includes (b) generating plasma by providing a radio-frequency wave after application of the voltage to the lower electrode is started in (a). In the method, (a) and (b) are performed without an object on a substrate support surface of the substrate support.

The technique according to the above aspect of the disclosure reduces the time taken to ignite plasma in the plasma processing performed without an object on a substrate support surface of a substrate support and reduces variations in the time taken to ignite plasma.

### BRIEF DESCRIPTION OF THE DRAWINGS

FIG. 1 is a schematic cross-sectional view of a plasma processing apparatus according to one exemplary embodiment.

FIG. 2 is a plan view of an example slot plate.

FIG. 3 is a plan view of an example dielectric window.

FIG. 4 is a cross-sectional view taken along line IV-IV in FIG. 3.

FIG. 5 is a plan view of the slot plate shown in FIG. 2 on the dielectric window shown in FIG. 3.

FIG. 6 is a flowchart of a plasma processing method according to one exemplary embodiment.

FIG. 7 is a flowchart of detailed processing in step S3 included in the plasma processing method according to one exemplary embodiment.

### DETAILED DESCRIPTION

Embodiments will now be described in detail with reference to the drawings. In the figures, like reference numerals denote like or corresponding components.

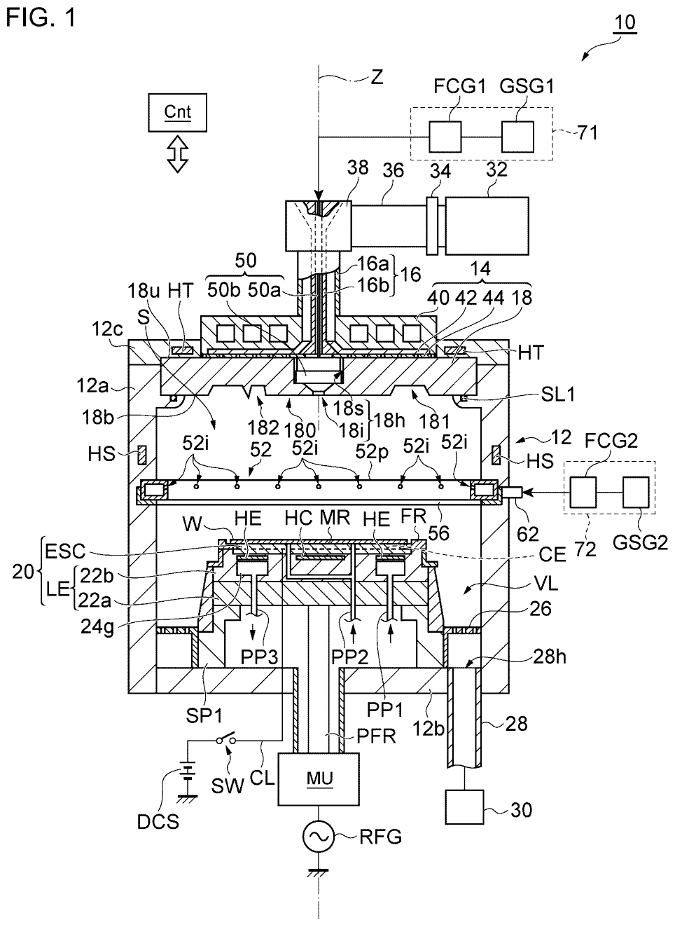

FIG. 1 is a schematic cross-sectional view of a plasma processing apparatus according to one exemplary embodiment. A plasma processing apparatus 10 shown in FIG. 1 includes a chamber 12. The chamber 12 defines a process space S for accommodating a substrate W.

The chamber 12 includes a side wall 12a. The chamber 12 may further include a bottom 12b and a ceiling 12c. The side wall 12a is substantially cylindrical and extends in the direction in which an axis Z extends. The axis Z extends, for example, through the center of a substrate support (described later) in the vertical direction. In one embodiment, the central axis of the side wall 12a is aligned with the axis Z. The side wall 12a has an inner diameter of, for example, 540 mm.

The bottom 12b is located at the lower end of the side wall 12a. The side wall 12a has an open upper end. The open upper end of the side wall 12a is closed by a dielectric window 18. The dielectric window 18 is held between the upper end of the side wall 12a and the ceiling 12c. A seal SL1 may be placed between the dielectric window 18 and the upper end of the side wall 12a. The seal SL1 is, for example, an O-ring for sealing the chamber 12 tightly.

The plasma processing apparatus 10 further includes a substrate support 20 in the chamber 12. The substrate support 20 is located below the dielectric window 18. The distance between the lower surface of the dielectric window 18 and the upper surface of the substrate support 20 is, for example, 245 mm. In one embodiment, the substrate support 20 includes a base LE and an electrostatic chuck (ESC).

The base LE includes a first plate 22a and a second plate 22b. The first plate 22a and the second plate 22b are both substantially disk-shaped and are formed from, for example, aluminum. The first plate 22a is supported by a cylindrical support SP1. The support SP1 extends vertically upward from the bottom 12b. The second plate 22b is on the first plate 22a and is electrically conductive with the first plate 22a.

The base LE is electrically coupled to a radio-frequency generator RFG, an example of a power supply, through a power feed rod PFR and a matching unit MU. The radio-frequency generator RFG provides radio-frequency (RF) bias power to the base LE. The radio-frequency generator RFG may generate RF bias power having a predetermined frequency, such as a frequency of 13.65 MHz, for controlling the energy of ions drawn to the substrate W. The matching unit MU accommodates a matcher for matching the impedance of the radio-frequency generator RFG with the impedance of a load, such as an electrode, plasma, or the chamber 12. The matcher may include, for example, a blocking capacitor for generating a self-bias voltage.

The electrostatic chuck ESC is located on the second plate 22b. The electrostatic chuck ESC has a surface facing the process space S to be a substrate support surface MR on which the substrate W is placeable. The substrate support surface MR is substantially circular and substantially perpendicular to the axis Z. The substrate support surface MR may have substantially the same diameter as the substrate W or a slightly smaller diameter than the substrate W. The substrate support surface MR defines the upper surface of the substrate support 20. The center of the substrate support surface MR, or in other words, the center of the substrate support 20, is aligned with the axis Z.

The electrostatic chuck ESC holds the substrate W with an electrostatic clamping force. The electrostatic chuck ESC includes a chuck electrode CE. The chuck electrode CE is located in a dielectric. The chuck electrode CE is coupled to a direct current (DC) power supply DCS with a switch SW and a covered wire CL. The electrostatic chuck ESC can electrostatically hold the substrate W on its upper surface with a Coulomb force generated by a DC voltage applied from the DC power supply DCS. The substrate W is surrounded annularly by an edge ring FR located radially outward from the electrostatic chuck ESC. The substrate W is loaded into the process space S and placed onto the electrostatic chuck ESC by a transferrer. The substrate W is lifted from the electrostatic chuck ESC and then unloaded from the process space S by the transferrer.

An annular channel 24g is defined inside the second plate 22b. The channel 24g receives a refrigerant supplied from a chiller unit through a pipe PP1. The refrigerant supplied to the channel 24g is collected in the chiller unit through a pipe PP3. In the plasma processing apparatus 10, a heat transfer gas (e.g., He gas) is supplied between the upper surface of the electrostatic chuck ESC and the back surface of the substrate W from a heat transfer gas supply through a supply pipe PP2.

The substrate support 20 and the side wall 12a define a space outward from the outer periphery of the substrate support 20. The space serves as an exhaust path VL that is annular in a plan view. An annular baffle plate 26 having multiple through-holes is located in the middle of the exhaust path VL in the direction in which the axis Z extends. The exhaust path VL connects with an exhaust pipe 28 having an outlet 28h. The exhaust pipe 28 is attached to the bottom 12b of the chamber 12. The exhaust pipe 28 is connected to an exhaust device 30. The exhaust device 30 includes a pressure adjuster and a vacuum pump such as a turbomolecular pump. The exhaust device 30 can decompress the process space S in the chamber 12 to an intended degree of vacuum. As the exhaust device 30 operates, the gas supplied to the substrate W flows along the surface of the substrate W toward the outer edge of the substrate W and is discharged from the outer periphery of the substrate support 20 through the exhaust path VL.

The plasma processing apparatus 10 may further include heaters HT, HS, HC, and HE as temperature controllers. The heater HT extends annularly inside the ceiling 12c and surrounds an antenna 14. The heater HS extends annularly inside the side wall 12a. The heater HC is inside the second plate 22b or inside the electrostatic chuck ESC. The heater HC is located below a middle portion of the substrate support surface MR described above, or more specifically, in an area intersecting with the axis Z. The heater HE extends annularly and surrounds the heater HC. The heater HE is located below the outer edge of the substrate support surface MR described above.

The plasma processing apparatus 10 may further include the antenna 14, a coaxial waveguide 16, a microwave generator 32, a tuner 34, a waveguide 36, and a mode converter 38. The antenna 14, the coaxial waveguide 16, the dielectric window 18, the microwave generator 32, the tuner 34, the waveguide 36, and the mode converter 38 are the generation sources of plasma and excite a gas introduced into the chamber.

The microwave generator 32 is an RF source in one embodiment. The microwave generator 32 generates microwaves with a frequency of, for example, 2.45 GHz. The microwave generator 32 is connected to an upper portion of the coaxial waveguide 16 through the tuner 34, the waveguide 36, and the mode converter 38. The coaxial waveguide 16 extends along the axis Z that is the central axis of the coaxial waveguide 16.

The coaxial waveguide 16 includes an outer conductor 16a and an inner conductor 16b. The outer conductor 16a is cylindrical and extends about the axis Z. The outer conductor 16a has its lower end electrically coupled to an upper portion of a cooling jacket 40 having an electrically conductive surface. The inner conductor 16b is coaxial with the outer conductor 16a inside the outer conductor 16a. The inner conductor 16b is cylindrical and extends about the axis Z. The inner conductor 16b has its lower end connected to a slot plate 44 in the antenna 14.

The antenna 14 allows microwaves to be introduced into the chamber 12. In one embodiment, the antenna 14 is a radial line slot antenna. The antenna 14 is located in the opening in the ceiling 12c and faces the substrate support 20. The antenna 14 includes a dielectric plate 42, the slot plate 44, and the dielectric window 18. The dielectric plate 42 is substantially disk-shaped and reduces the wavelength of microwaves. The dielectric plate 42 is formed from, for example, quartz or alumina. The dielectric plate 42 is held between the slot plate 44 and the lower surface of the cooling jacket 40.

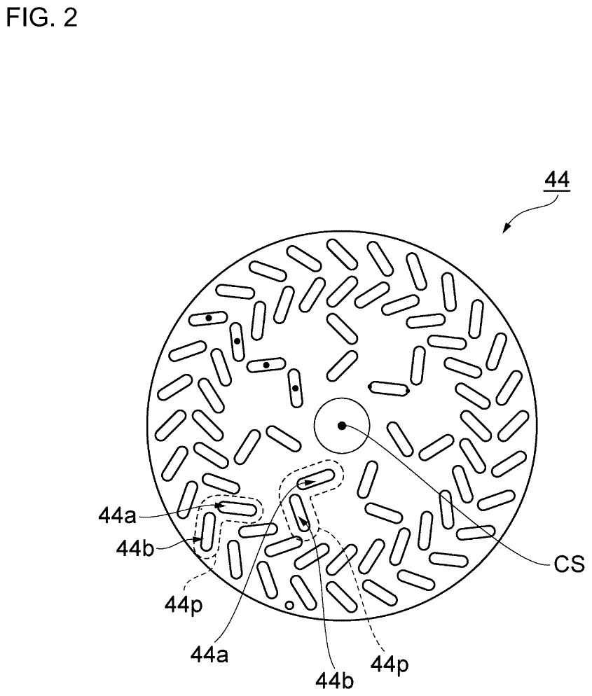

FIG. 2 is a plan view of an example slot plate. The slot plate 44 is thin and disk-shaped. The slot plate 44 has two flat surfaces in the thickness direction. The slot plate 44 has a center CS aligned with the axis Z. The slot plate 44 has multiple slot pairs 44p. Each slot pair 44p has two slots 44a and 44b extending through the slot plate 44 in the thickness direction. The slots 44a and 44b are elliptical as viewed from above. In each slot pair 44p, the direction along the major axis of the slot 44a and the direction along the major axis of the slot 44b intersect with or perpendicular to each other. The slot pairs 44p are arranged circumferentially. In the example shown in FIG. 2, the slot pairs 44p are arranged circumferentially along two concentric circles. The slot pairs 44p on each concentric circle are arranged at substantially equal intervals. The slot plate 44 is located on an upper surface 18u of the dielectric window 18.

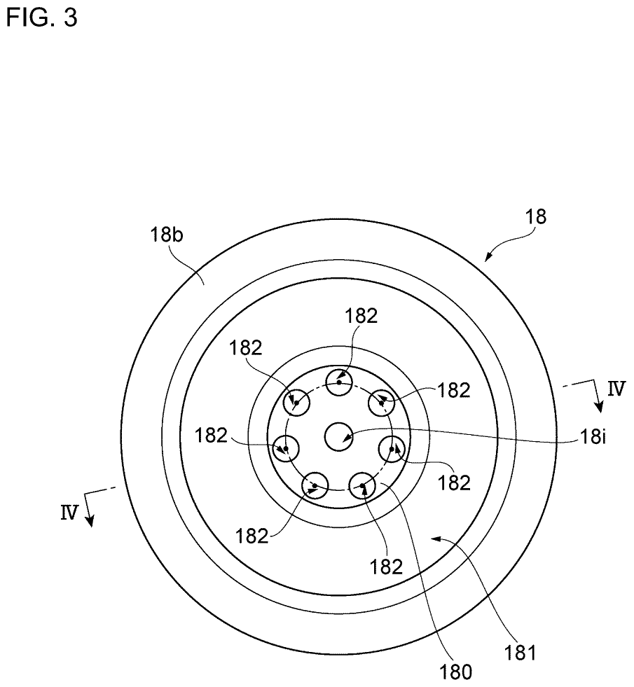

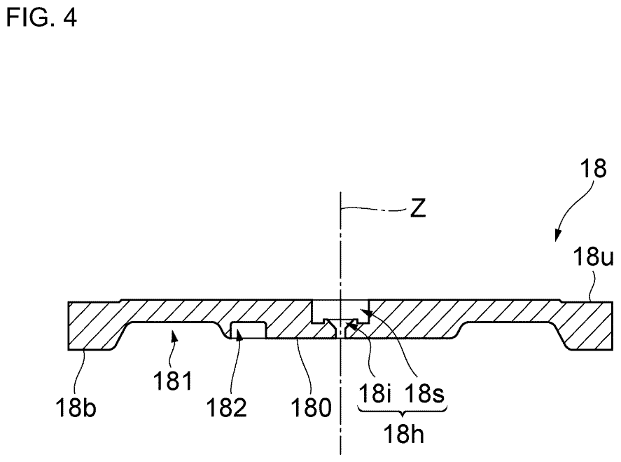

FIG. 3 is a plan view of an example dielectric window. FIG. 4 is a cross-sectional view taken along line IV-IV in FIG. 3. As shown in FIGS. 3 and 4, the dielectric window 18 is substantially disk-shaped and formed from a dielectric material such as quartz. The dielectric window 18 has a through-hole 18h in its center. The through-hole 18h has its upper portion being a space 18s to accommodate an injector 50b in a central inlet unit 50 (described later) and its lower portion being a gas outlet 18i in the central inlet unit 50 (described later). The dielectric window 18 has its central axis aligned with the axis Z.

The dielectric window 18 has a lower surface 18b opposite to the upper surface 18u. The lower surface 18b is exposed in the process space S and is the surface on which plasma is generated. The lower surface 18b has various features. More specifically, the lower surface 18b has a flat surface 180 in its central area surrounding the gas outlet 18i. The flat surface 180 is perpendicular to the axis Z. The lower surface 18b has an annular first recess 181. The first recess 181 is located radially outward from the flat surface 180. The first recess 181 is annular and continuous from the flat surface 180 and is tapered inward in the thickness direction of the dielectric window 18.

The lower surface 18b also has multiple second recesses 182. The second recesses 182 are recessed inward in the thickness direction from the flat surface 180. In the example shown in FIGS. 3 and 4, the second recesses 182 are seven second recesses. The second recesses 182 are arranged at equal intervals circumferentially. The second recesses 182 are circular as viewed from above on a plane perpendicular to the axis Z.

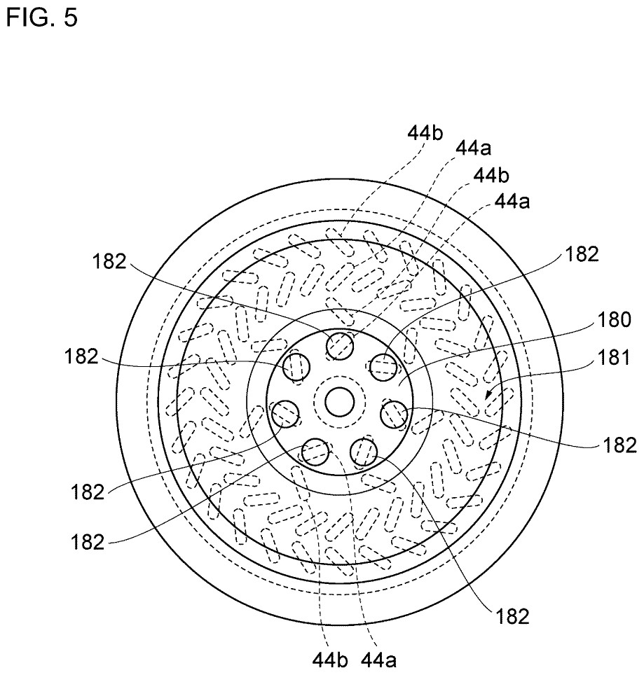

FIG. 5 is a plan view of the slot plate shown in FIG. 2 on the dielectric window shown in FIG. 3, with the dielectric window 18 viewed from below. As shown in FIG. 5, in a plan view, or more specifically, as viewed along the axis Z, the slot pairs 44p arranged along the radially outward concentric circle overlap the first recess 181. The slots 44b in the slot pairs 44p arranged along the radially inward concentric circle overlap the first recess 181. The slots 44a in the slot pairs 44p arranged along the radially inward concentric circle overlap the multiple second recesses 182.

Referring back to FIG. 1, in the plasma processing apparatus 10, microwaves generated by the microwave generator 32 propagate through the coaxial waveguide 16 to the dielectric plate 42 and to the dielectric window 18 through the slots 44a and 44b in the slot plate 44. Immediately below the dielectric window 18, the microwave energy concentrates on the first recess 181 and the second recesses 182 defined by the portions of the dielectric window 18 with relatively small thicknesses. The plasma processing apparatus 10 can thus generate plasma spread in a stable manner in the circumferential and radial directions.

The plasma processing apparatus 10 includes the central inlet unit 50 and a peripheral inlet unit 52. The central inlet unit 50 includes a conduit 50a, the injector 50b, and the gas outlet 18i. The conduit 50a is placed through the inner hole of the inner conductor 16b in the coaxial waveguide 16. The conduit 50a has an end extending into the space 18s (refer to FIG. 4) defined by the dielectric window 18 along the axis Z. The space 18s accommodates the injector 50b below the end of the conduit 50a. The injector 50b has multiple through-holes each extending in the direction in which the axis Z extends. The dielectric window 18 has a portion serving as the gas outlet 18i described above. The gas outlet 18i extends continuously under the space 18s along the axis Z. The central inlet unit 50 having the above structure supplies a gas into the injector 50b through the conduit 50a and discharges the gas from the injector 50b through the gas outlet 18i. The central inlet unit 50 thus discharges the gas immediately below the dielectric window 18 along the axis Z. In other words, the central inlet unit 50 introduces a gas into a plasma generating region with a high electron temperature. The gas discharged from the central inlet unit 50 flows toward the middle of the substrate W substantially along the axis Z.

The plasma processing apparatus 10 according to one embodiment includes a first gas supply 71 that supplies a gas into the chamber 12. The central inlet unit 50 is connected to the first gas supply 71. The first gas supply 71 includes a first flow rate controller set FCG1 and a first gas source set GSG1. The central inlet unit 50 is connected to the first gas source set GSG1 through the first flow rate controller set FCG1. The first gas source set GSG1 includes multiple first gas sources. The first gas sources include sources of multiple gases used with a plasma processing method (described later). The gases used with the plasma processing method include one or more gases included in a process gas, and a noble gas such as an argon (Ar) gas. The process gas may be a cleaning gas. The cleaning gas includes, for example, a sulfur hexafluoride (SF₆) gas and an oxygen (O₂) gas. The first flow rate controller set FCG1 includes multiple flow controllers and multiple open-close valves. Each first gas source is connected to the central inlet unit 50 through the corresponding flow controller and the corresponding open-close valve in the first flow rate controller set FCG1.

The peripheral inlet unit 52 is between the gas outlet 18i in the central inlet unit 50 and the upper surface of the substrate support 20 in the height direction, or more specifically, in the direction in which the axis Z extends. The peripheral inlet unit 52 introduces a gas into the process space S along the side wall 12a. The peripheral inlet unit 52 has multiple gas outlets 52i. The gas outlets 52i are arranged circumferentially below the gas outlet 18i and above the substrate support 20.

The peripheral inlet unit 52 includes, for example, an annular tube 52p. The tube 52p is, for example, placed 90 mm upward from the upper surface of the substrate support 20. The tube 52p has the gas outlets 52i. The annular tube 52p is formed from, for example, quartz. In one embodiment, as shown in FIG. 1, the annular tube 52p is in contact with the side wall 12a.

The plasma processing apparatus 10 according to one embodiment includes a second gas supply 72 that supplies a gas into the chamber 12. The annular tube 52p in the peripheral inlet unit 52 is connected to the second gas supply 72. The second gas supply 72 includes a second flow rate controller set FCG2 and a second gas source set GSG2. The annular tube 52p in the peripheral inlet unit 52 is connected to the second gas source set GSG2 through a gas supply block 62 and the second flow rate controller set FCG2. The second gas source set GSG2 includes sources of the same gases as the first gas source set GSG1. The second flow rate controller set FCG2 includes multiple flow controllers and multiple open-close valves. Each second gas source is connected to the peripheral inlet unit 52 through the corresponding flow controller and the corresponding open-close valve in the second flow rate controller set FCG2.

The plasma processing apparatus 10 may individually control the type of gas introduced from the central inlet unit 50 into the process space S and the flow rates of one or more gases introduced from the central inlet unit 50 into the process space S. The plasma processing apparatus 10 may individually control the type of gas introduced from the peripheral inlet unit 52 into the process space S and the flow rates of one or more gases introduced from the peripheral inlet unit 52 into the process space S.

As shown in FIG. 1, the plasma processing apparatus 10 may further include a controller Cnt. The controller Cnt may be a programmable computer implemented by, for example, processing circuitry including a CPU (Central Processing Unit). The controller Cnt may control the components of the plasma processing apparatus 10 based on a recipe and a program. For example, the controller Cnt transmits a control signal to the flow controllers and the open-close valves in the first flow rate controller set FCG1, and adjusts the type and the flow rate of the gas to be introduced from the central inlet unit 50. The controller Cnt also transmits a control signal to the flow controllers and the open-close valves in the second flow rate controller set FCG2, and adjusts the type and the flow rate of the gas to be introduced from the peripheral inlet unit 52. The controller Cnt may provide a control signal to the microwave generator 32, the radio-frequency generator RFG, and the exhaust device 30 to control the power level of the microwaves, the power level of and the on-off state of the RF bias power, and the pressure inside the chamber 12. The controller Cnt may also transmit a control signal to a heater power supply connected to the heaters HT, HS, HC, and HE to adjust the temperatures of the heaters HT, HS, HC, and HE.

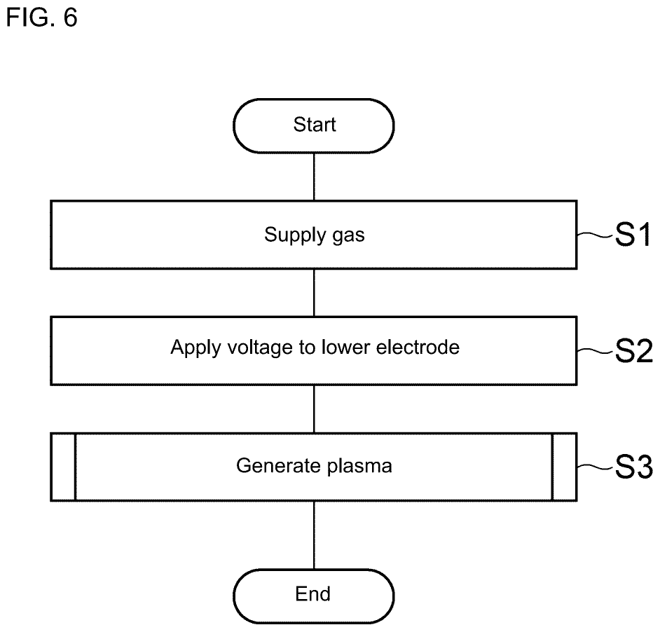

A plasma processing method according to one exemplary embodiment will now be described. FIG. 6 is a flowchart of the plasma processing method according to one exemplary embodiment. The operation of the plasma processing apparatus 10 with the plasma processing method shown in FIG. 6 will also be described. The plasma processing apparatus 10 may have its components controlled by the controller Cnt in the steps included in the plasma processing method shown in FIG. 6.

With the plasma processing method shown in FIG. 6, plasma processing is performed without an object such as the substrate W on the substrate support surface MR of the substrate support 20. The plasma processing includes, for example, cleaning the surfaces inside the chamber 12. When an object such as the substrate W is on the substrate support surface MR before the plasma processing method is started, the object is unloaded from the process space S by the transferrer.

The plasma processing method shown in FIG. 6 includes steps S1 to S3. In step S1, a gas is supplied into the chamber 12. The gas supplied into the chamber 12 in step S1 is a noble gas such as an argon gas. The gas supplied into the chamber 12 in step S1 may be the noble gas alone. In step S1, the gas is supplied from at least one of the first gas supply 71 or the second gas supply 72. During the processing in the steps in the plasma processing method shown in FIG. 6, the pressure in the chamber 12 is set to a specified pressure by the exhaust device 30.

Step S2 is performed with the gas (e.g., noble gas) being supplied into the chamber 12 continuously from step S1. In step S2, a voltage is applied to a lower electrode in the substrate support 20. More specifically, a voltage from the DC power supply DCS is applied to the chuck electrode CE serving as the lower electrode in the substrate support 20. Instead of or in addition to applying the voltage to the chuck electrode CE, RF bias power from the radio-frequency generator RFG may be provided to the base LE serving as the lower electrode. In step S2, the electron density increases in the chamber 12. The lower electrode that receives RF bias power from the radio-frequency generator RFG may be another electrode in the substrate support 20.

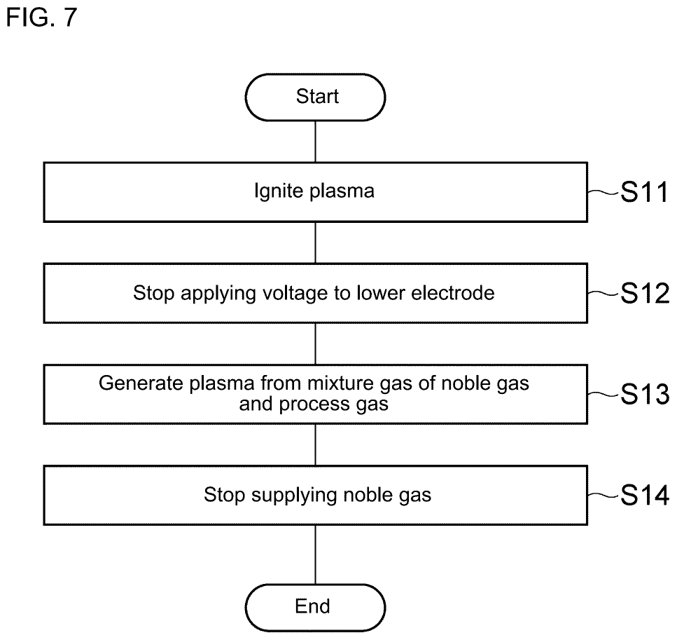

Step S3 is then performed. In step S3, plasma is generated in the chamber 12. FIG. 7 is a flowchart of detailed processing in step S3 according to one exemplary embodiment. In one embodiment, step S3 may include steps S11 to S14 as shown in FIG. 7.

In step S11, with the gas (e.g., noble gas) being supplied into the chamber 12 continuously from step S1, microwaves as RF waves are provided into the chamber 12. In step S11, plasma is thus ignited in the chamber 12. The microwaves are generated by the microwave generator 32 and introduced into the chamber 12 through the antenna 14. The microwaves are provided in step S11 after, for example, the voltage applied in step S2 enters a stable state. The microwaves may be provided in step S11 about one second after application of the voltage to the lower electrode is started in step S2. In some embodiments, the microwaves may be provided in step S11 about 0.1 seconds after the voltage applied to the lower electrode in step S2 is determined to be stable. The microwaves provided in step S11 cause plasma to be ignited in the chamber 12.

Step S12 is then performed. In step S12, the voltage applied to the lower electrode is stopped. More specifically, any voltage applied from the DC power supply DCS to the chuck electrode CE in the substrate support 20 is stopped. Any RF bias power provided from the radio-frequency generator RFG to the base LE is stopped. Step S12 is, for example, performed about one second after microwaves are started to be provided in step S11.

Step S13 is then performed. In step S13, plasma is generated from a mixture gas of the noble gas and a process gas in the chamber 12. The process gas is, for example, the cleaning gas described above. The noble gas is supplied into the chamber 12 in step S13 continuously from step S1. In step S13, the process gas is further supplied into the chamber 12. The mixture gas is supplied from at least one of the first gas supply 71 or the second gas supply 72.

In step S13, microwaves as RF waves are introduced into the chamber 12 with the plasma generated in step S11 being maintained. The microwaves are generated by the microwave generator 32 and introduced into the chamber 12 through the antenna 14. Plasma is thus generated from the mixture gas in the chamber 12.

Step S14 is then performed. In step S14, with the process gas and the RF waves (microwaves) being provided into the chamber 12 continuously from step S13, the noble gas supplied into the chamber 12 is stopped. With this plasma processing method, the surfaces inside the chamber 12 are cleaned with, for example, plasma generated from the cleaning gas in steps S13 and S14.

With the plasma processing method implementable with the plasma processing apparatus 10 described above, RF waves (microwaves) are provided into the chamber 12 in which the electron density is increased by the voltage applied to the lower electrode. This reduces the time taken to ignite plasma after the RF waves (microwaves) are started to be provided and reduces variations in the time taken to ignite plasma. The plasma processing performed without an object on the substrate support surface MR of the substrate support 20 can thus take a shorter time to ignite plasma and have less variation in the time taken to ignite plasma. The voltage applied to the lower electrode increases the electron density in the chamber 12 by drawing charged particles such as ions in the chamber 12 to the substrate support 20 and allowing discharge of secondary electrons from the substrate support 20.

With the plasma processing method implementable with the plasma processing apparatus 10, plasma is generated from the process gas (e.g., cleaning gas) in step S13 with the plasma generated from the noble gas being maintained. Plasma can thus be generated easily from the process gas.

Although the exemplary embodiments have been described above, the embodiments are not restrictive, and various additions, omissions, substitutions, and changes may be made. The components in the different embodiments may be combined to form another embodiment.

In another embodiment, a plasma processing apparatus different from the plasma processing apparatus 10 may excite a gas using microwaves. In still another embodiment, the plasma processing apparatus may be other than the plasma processing apparatus that excites a gas using microwaves. For example, the plasma processing apparatus may be a capacitively coupled plasma processing apparatus or an inductively coupled plasma processing apparatus. In such a plasma processing apparatus, the RF source may generate RF power in a high-frequency band as RF waves.

The plasma processing apparatus may include, instead of the radio-frequency generator RFG, a bias power supply electrically coupled to the base LE. The bias power supply may cyclically apply a pulse of the voltage to the base LE or another electrode in the substrate support 20.

The present disclosure is not limited to only the above-described embodiments, which are merely exemplary. It will be appreciated by those skilled in the art that the disclosed systems and/or methods can be embodied in other specific forms without departing from the spirit of the disclosure or essential characteristics thereof. The presently disclosed embodiments are therefore considered to be illustrative and not restrictive. The disclosure is not exhaustive and should not be interpreted as limiting the claimed invention to the specific disclosed embodiments. In view of the present disclosure, one of skill in the art will understand that modifications and variations are possible in light of the above teachings or may be acquired from practicing of the disclosure.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

Various exemplary embodiments E1 to E16 included in the disclosure will now be described.

### E1

A plasma processing method implementable with a plasma processing apparatus, the method comprising:
(a) applying a voltage to a lower electrode in a substrate support with a gas being supplied into a chamber in the plasma processing apparatus, the substrate support being located in the chamber; and
(b) generating plasma by providing a radio-frequency wave after application of the voltage to the lower electrode is started in (a), wherein (a) and (b) are performed without an object on a substrate support surface of the substrate support.

In embodiment E1, RF waves are provided into the chamber in which the electron density is increased by the voltage applied to the lower electrode. This reduces the time taken to ignite plasma after the RF waves are started to be provided and reduces variations in the time taken to ignite plasma. The method according to embodiment E1 thus reduces the time taken to ignite plasma in the plasma processing performed without an object on a substrate support surface of a substrate support and reduces variations in the time taken to ignite plasma.

### E2

The plasma processing method according to E1, wherein
(b) includes
   (b-1) igniting plasma by providing the radio-frequency wave with a noble gas being supplied into the chamber, and
   (b-2) generating plasma from a mixture gas of the noble gas and a cleaning gas by providing the radio-frequency wave with the plasma generated from the noble gas being maintained.

The method according to embodiment E2 allows generation of plasma from the mixture gas containing the cleaning gas with the ignited plasma being maintained.

### E3

The plasma processing method according to E2, wherein applying the voltage to the lower electrode is stopped after (b-1) and before (b-2).

### E4

The plasma processing method according to E2 or E3, wherein
(b) further includes (b-3) stopping a supply of the noble gas after (b-2) and generating plasma from the cleaning gas.

### E5

The plasma processing method according to any one of E1 to E4, wherein
the lower electrode is a bias electrode, and
applying the voltage to the lower electrode includes providing radio-frequency bias power to the lower electrode or cyclically applying a pulse of the voltage to the lower electrode.

### E6

The plasma processing method according to any one of E1 to E4, wherein
the substrate support further includes an electrostatic chuck,
the electrostatic chuck includes a chuck electrode, and applying the voltage to the lower electrode includes applying a direct current voltage to the chuck electrode.

### E7

The plasma processing method according to any one of E1 to E6, wherein
the radio-frequency wave is a microwave or radio-frequency power in a high-frequency band.

### E8

The plasma processing method according to any one of E1 to E7, wherein
the radio-frequency wave is a microwave introduced into the chamber through a radial line slot antenna.

### E9

A plasma processing apparatus, comprising:
a chamber;
a gas supply configured to supply a gas into the chamber;
a substrate support in the chamber, the substrate support including a lower electrode; a radio-frequency source configured to generate a radio-frequency wave to generate plasma from the gas in the chamber; and
a power supply electrically coupled to the lower electrode,
wherein the power supply applies a voltage to the lower electrode without an object on a substrate support surface of the substrate support and with the gas being supplied from the gas supply into the chamber, and
the radio-frequency source provides the radio-frequency wave to generate plasma after application of the voltage to the lower electrode is started without an object on the substrate support surface.

In embodiment E9, RF waves are provided into the chamber in which the electron density is increased by the voltage applied to the lower electrode. This reduces the time taken to ignite plasma after the RF waves are started to be provided and reduces variations in the time taken to ignite plasma. The structure according to embodiment E9 thus reduces the time taken to ignite plasma in the plasma processing performed without an object on a substrate support surface of a substrate support and reduces variations in the time taken to ignite plasma.

### E10

The plasma processing apparatus according to E9, wherein
the radio-frequency source ignites plasma by providing the radio-frequency wave with a noble gas being supplied into the chamber from the gas supply, and
the radio-frequency source generates plasma from a mixture gas of the noble gas and a cleaning gas supplied from the gas supply by providing the radio-frequency wave with the plasma generated from the noble gas being maintained.

The structure according to embodiment E10 allows generation of plasma from the mixture gas containing the cleaning gas with the ignited plasma being maintained.

### E11

The plasma processing apparatus according to E10, wherein
the power supply stops applying the voltage to the lower electrode after the plasma generated from the noble gas is ignited and before plasma is generated from the mixture gas of the noble gas and the cleaning gas.

### E12

The plasma processing apparatus according to E10 or E11, wherein
the gas supply stops supplying the noble gas after the plasma is generated from the mixture gas, and
the radio-frequency source generates plasma from the cleaning gas by providing the radio-frequency wave after a supply of the noble gas is stopped.

### E13

The plasma processing apparatus according to any one of E9 to E12, wherein
the lower electrode is a bias electrode, and
the power supply applies the voltage to the lower electrode by providing radio-frequency bias power to the lower electrode or cyclically applying a pulse of the voltage to the lower electrode.

### E14

The plasma processing apparatus according to any one of E9 to E12, wherein
the substrate support further includes an electrostatic chuck,
the electrostatic chuck includes a chuck electrode, and
the power supply applies the voltage to the lower electrode by applying a direct current voltage to the chuck electrode.

### E15

The plasma processing apparatus according to any one of E9 to E14, wherein
the radio-frequency source generates the radio-frequency wave being a microwave or radio-frequency power in a high-frequency band.

### E16

The plasma processing apparatus according to any one of E9 to E15, wherein
the radio-frequency source generates the radio-frequency wave being a microwave, and
the plasma processing apparatus further comprises a radial line slot antenna to introduce the microwave into the chamber.

The exemplary embodiments according to the disclosure have been described by way of example, and various changes may be made without departing from the scope and spirit of the disclosure. The exemplary embodiments disclosed above are thus not restrictive, and the true scope and spirit of the disclosure are defined by the appended claims.

### REFERENCE SIGNS LIST

10 Plasma processing apparatus
20 Substrate support
71 First gas supply
72 Second gas supply
CE Chuck electrode
Cnt Controller
DCS Direct current power supply
ESC Electrostatic chuck
LE Base
MR Substrate support surface
RFG Radio-frequency generator

1. A plasma processing method implementable with a plasma processing apparatus including circuitry, the method comprising:
applying a voltage to a lower electrode in a substrate support with a gas being supplied into a chamber in the plasma processing apparatus, the substrate support being located in the chamber; and
generating plasma by providing a radio-frequency wave after application of the voltage to the lower electrode is started,
wherein the applying the voltage to the lower electrode and the generating the plasma are performed without an object on a substrate support surface of the substrate support.

2. The plasma processing method according to claim 1, wherein
the generating the plasma includes
igniting plasma by providing the radio-frequency wave with a noble gas being supplied into the chamber, and
generating plasma from a mixture gas of the noble gas and a cleaning gas by providing the radio-frequency wave with the plasma generated from the noble gas being maintained.

3. The plasma processing method according to claim 2, wherein
applying the voltage to the lower electrode is stopped after the igniting of the plasma and before the generating of the plasma from the mixture gas of the noble gas and the cleaning gas.

4. The plasma processing method according to claim 2, wherein
the generating the plasma further includes stopping a supply of the noble gas after the generating of the plasma from the mixture gas of the noble gas and the cleaning gas, and generating plasma from the cleaning gas.

5. The plasma processing method according to claim 1, wherein
the lower electrode is a bias electrode, and
applying the voltage to the lower electrode includes providing radio-frequency bias power to the lower electrode or cyclically applying a pulse of the voltage to the lower electrode.

6. The plasma processing method according to claim 1, wherein
the substrate support further includes an electrostatic chuck,
the electrostatic chuck includes a chuck electrode, and
applying the voltage to the lower electrode includes applying a direct current voltage to the chuck electrode.

7. The plasma processing method according to claim 1, wherein
the radio-frequency wave is a microwave or radio-frequency power in a high-frequency band.

8. The plasma processing method according to claim 1, wherein
the radio-frequency wave is a microwave introduced into the chamber through a radial line slot antenna.

9. A plasma processing apparatus, comprising:
a chamber;
a gas supply configured to supply a gas into the chamber;
a substrate support in the chamber, the substrate support including a lower electrode;
a radio-frequency source configured to generate a radio-frequency wave to generate plasma from the gas in the chamber; and
a power supply electrically coupled to the lower electrode,
wherein the power supply applies a voltage to the lower electrode without an object on a substrate support surface of the substrate support and with the gas being supplied from the gas supply into the chamber, and
the radio-frequency source provides the radio-frequency wave to generate plasma after application of the voltage to the lower electrode is started without an object on the substrate support surface.

10. The plasma processing apparatus according to claim 9, wherein
the radio-frequency source ignites plasma by providing the radio-frequency wave with a noble gas being supplied into the chamber from the gas supply, and
the radio-frequency source generates plasma from a mixture gas of the noble gas and a cleaning gas supplied from the gas supply by providing the radio-frequency wave with the plasma generated from the noble gas being maintained.

11. The plasma processing apparatus according to claim 10, wherein
the power supply stops applying the voltage to the lower electrode after the plasma generated from the noble gas is ignited and before plasma is generated from the mixture gas of the noble gas and the cleaning gas.

12. The plasma processing apparatus according to claim 10, wherein
the gas supply stops supplying the noble gas after the plasma is generated from the mixture gas, and
the radio-frequency source generates plasma from the cleaning gas by providing the radio-frequency wave after a supply of the noble gas is stopped.

13. The plasma processing apparatus according to claim 9, wherein
the lower electrode is a bias electrode, and
the power supply applies the voltage to the lower electrode by providing radio-frequency bias power to the lower electrode or cyclically applying a pulse of the voltage to the lower electrode.

14. The plasma processing apparatus according to claim 9, wherein
the substrate support further includes an electrostatic chuck,
the electrostatic chuck includes a chuck electrode, and
the power supply applies the voltage to the lower electrode by applying a direct current voltage to the chuck electrode.

15. The plasma processing apparatus according to claim 9, wherein
the radio-frequency source generates the radio-frequency wave being a microwave or radio-frequency power in a high-frequency band.

16. The plasma processing apparatus according to claim 9, wherein
the radio-frequency source generates the radio-frequency wave being a microwave, and
the plasma processing apparatus further includes a radial line slot antenna to introduce the microwave into the chamber.

17. The plasma processing method according to claim 3, wherein
the generating the plasma further includes stopping a supply of the noble gas after the generating of the plasma from the mixture gas of the noble gas and the cleaning gas, and generating plasma from the cleaning gas.

18. The plasma processing method according to claim 2, wherein
the lower electrode is a bias electrode, and
applying the voltage to the lower electrode includes providing radio-frequency bias power to the lower electrode or cyclically applying a pulse of the voltage to the lower electrode.

19. The plasma processing method according to claim 3, wherein
the lower electrode is a bias electrode, and
applying the voltage to the lower electrode includes providing radio-frequency bias power to the lower electrode or cyclically applying a pulse of the voltage to the lower electrode.

20. The plasma processing method according to claim 2, wherein
the substrate support further includes an electrostatic chuck,
the electrostatic chuck includes a chuck electrode, and
applying the voltage to the lower electrode includes applying a direct current voltage to the chuck electrode.
